(19) United States
(12) Patent Application Publication
(10) Pub. No.: US 2025/0316523 A1
(43) Pub. Date: Oct. 9, 2025

(54) WAFER HOLDING TOOL

(71) Applicant: NANYA TECHNOLOGY CORPORATION, New Taipei city (TW)

(72) Inventor: Yi-Wen LIU, New Taipei City (TW)

(21) Appl. No.: 18/628,559

(22) Filed: Apr. 5, 2024

(51) Int. Cl. H01L 21/687; B65G 47/90; H01L 21/677; H01L 21/68

(52) U.S. Cl. CPC H01L 21/68707; B65G 47/90; H01L 21/67778; H01L 21/68

(57) ABSTRACT

A wafer holding tool includes a main frame, a plurality of abutting device, a moving device and a handle. The abutting devices are disposed on the main frame about a center. Each of the abutting devices is at least partially movable along a first direction towards the center to abut against a wafer. The moving device is disposed on the main frame and configured to hold and move the wafer after the wafer is abutted by the abutting devices. The handle is disposed on the main frame and extends along a second direction aligning with the center.

### BACKGROUND

### Technical Field

The present disclosure relates to wafer holding tools. More particularly, the present disclosure relates to wafer holding tools used for putting wafers into a front opening unified pod (FOUP).

### Description of Related Art

As the demand for electronic devices has been increasing nowadays, the quality of various components of electronic devices becomes an important issue of the industry. Apart from improving the technology of manufacture of the components, the measures to guarantee the quality of the components during production is also highly concerned.

For example, front opening unified pods (FOUPs) are commonly used to accommodate wafers during the production process in the industry of semiconductors. Hence, convenient and efficient measures for putting wafers into a FOUP are important to increase the yield rate of the wafers and thus help to decrease the cost of production.

### SUMMARY

A technical aspect of the present disclosure is to provide a wafer holding tool, which can allow a wafer to be held and manipulated safely without using bare hand(s).

According to an embodiment of the present disclosure, a wafer holding tool includes a main frame, a plurality of abutting device, a moving device and a handle. The abutting devices are disposed on the main frame about a center. Each of the abutting devices is at least partially movable along a first direction towards the center to abut against a wafer. The moving device is disposed on the main frame and configured to hold and move the wafer after the wafer is abutted by the abutting devices. The handle is disposed on the main frame and extends along a second direction aligning with the center.

In one or more embodiments of the present disclosure, each of the abutting devices includes a driving portion and a spade. The driving portion is connected with the main frame. The spade is movably connected with the driving portion. The driving portion is configured to drive the spade to move along the first direction.

In one or more embodiments of the present disclosure, each of the spades has an abutting surface inclined to a corresponding one of the first directions.

In one or more embodiments of the present disclosure, the abutting devices are symmetrically distributed about the center.

In one or more embodiments of the present disclosure, the main frame has an inner edge circularly curved about the center. Two opposite ends of the inner edge define an opening therebetween.

In one or more embodiments of the present disclosure, the wafer holding tool further includes a first controlling device. The first controlling device is disposed on the handle and connected with the abutting devices. The first controlling device is configured to control the abutting devices to at least partially move to or away from the center.

In one or more embodiments of the present disclosure, the first controlling device is further configured to lock the abutting devices.

In one or more embodiments of the present disclosure, the moving device includes a clamp and an extendable portion. The clamp is configured to hold the wafer. The extendable portion is connected between the clamp and the main frame. The extendable portion is configured to extend or retract along the second direction to move the clamp relative to the main frame.

In one or more embodiments of the present disclosure, the wafer holding tool further includes a second controlling device and a third controlling device. The second controlling device is disposed on the handle and connected with the extendable portion. The second controlling device is configured to control the extendable portion to at least partially extend or contract. The third controlling device is disposed on the handle and connected with the extendable portion and the clamp. The third controlling device is configured to control the clamp to open or close and to further control the extendable portion to at least partially extend or contract.

In one or more embodiments of the present disclosure, the third controlling device is further configured to lock the extendable portion and the clamp.

In one or more embodiments of the present disclosure, the wafer holding tool further includes at least a pair of positioning protrusions. The positioning protrusions are separated from each other and disposed on a side of the main frame away from the handle.

According to an embodiment of the present disclosure, a wafer holding tool includes a C-shaped frame, a handle and a moving device. The C-shaped frame defines an opening. The handle is disposed at a side of the C-shaped frame opposite to the opening. The moving device is disposed on the main frame and configured to clamp and move a wafer along an extension direction of the handle.

In one or more embodiments of the present disclosure, the wafer holding tool further includes a plurality of abutting devices. The abutting devices are disposed on the C-shaped frame and configured to move to abut against the wafer in a surrounding manner before the wafer is clamped by the moving device.

In one or more embodiments of the present disclosure, each of the abutting devices includes a driving portion and a spade. The driving portion is connected with the C-shaped frame. The spade is movably connected with the driving portion. The driving portion is configured to drive the spade to move relative to the C-shaped frame.

In one or more embodiments of the present disclosure, each of the spades has an abutting surface inclined to a moving direction of a corresponding one of the spades.

In one or more embodiments of the present disclosure, the wafer holding tool further includes a first controlling device. The first controlling device is disposed on the handle and connected with the driving portions. The first controlling device is configured to control the driving portions to drive the spades to move to abut against or leave from the wafer.

In one or more embodiments of the present disclosure, the moving device includes a clamp and an extendable portion. The clamp is configured to hold the wafer. The extendable portion is connected between the clamp and the C-shaped frame. The extendable portion is configured to extend or retract to move the clamp relative to the main frame.

In one or more embodiments of the present disclosure, the wafer holding tool further includes a second controlling device and a third controlling device. The second controlling device is disposed on the handle and connected with the extendable portion. The second controlling device is configured to control the extendable portion to at least partially extend or contract. The third controlling device is disposed on the handle and connected with the extendable portion and the clamp. The third controlling device is configured to control the clamp to open or close and to further control the extendable portion to at least partially extend or contract.

In one or more embodiments of the present disclosure, the wafer holding tool further includes at least a pair of positioning protrusions. The positioning protrusions are separated from each other and disposed on a side of the C-shaped frame away from the handle.

The above-mentioned embodiments of the present disclosure have at least the following advantages:

(1) Since the wafer holding tool can be used to securely hold and put a wafer into a FOUP, the user is avoided from touching the wafer directly with his bare hand(s). Thus, the risk of contamination of the wafer is reduced.

(2) Since a wafer can be lifted up by the spades of the abutting devices when the spades abut against the edge of the wafer from different directions, the clamp of the moving device can easily hold and clamp the edge of the wafer even if the wafer if originally placed on a flat surface.

### BRIEF DESCRIPTION OF THE DRAWINGS

The disclosure can be more fully understood by reading the following detailed description of the embodiments, with reference made to the accompanying drawings as follows:

FIG. 1 is a top view of a wafer holding tool according to an embodiment of the present disclosure;

FIG. 2 is a front view of the wafer holding tool of FIG. 1;

FIG. 3 is a side view of the wafer holding tool of FIG. 1;

FIG. 4 is a cross-sectional view along the section line A-A of FIG. 1, in which the abutting devices are away from a wafer;

FIG. 5 is an operational presentation of the wafer holding tool of FIG. 4, in which the abutting devices abut against the wafer and the wafer is lifted up;

FIGS. 6-7 are partially enlarged side views of the moving device of FIGS. 2-3; and

FIG. 8 is a top view of the wafer holding tool of FIG. 1, in which the wafer is moved by the moving device relative to the main frame.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

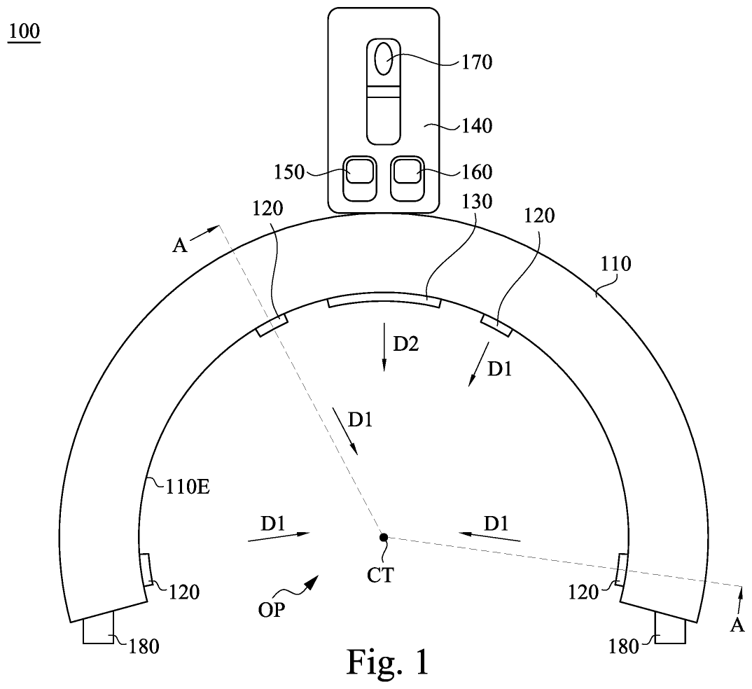

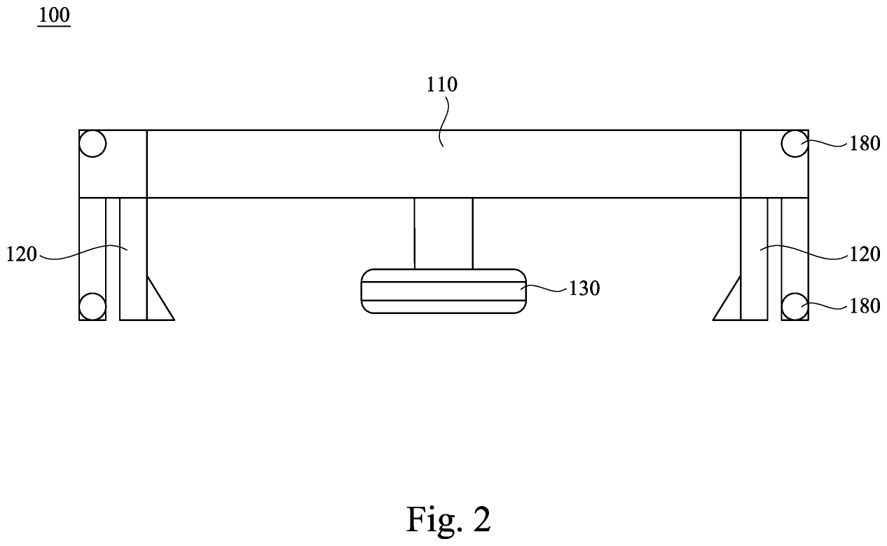

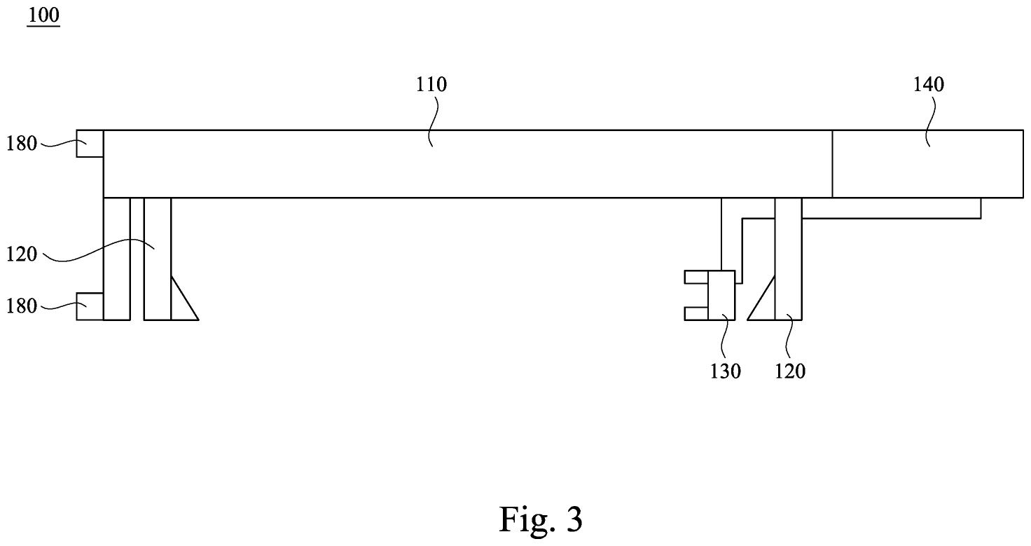

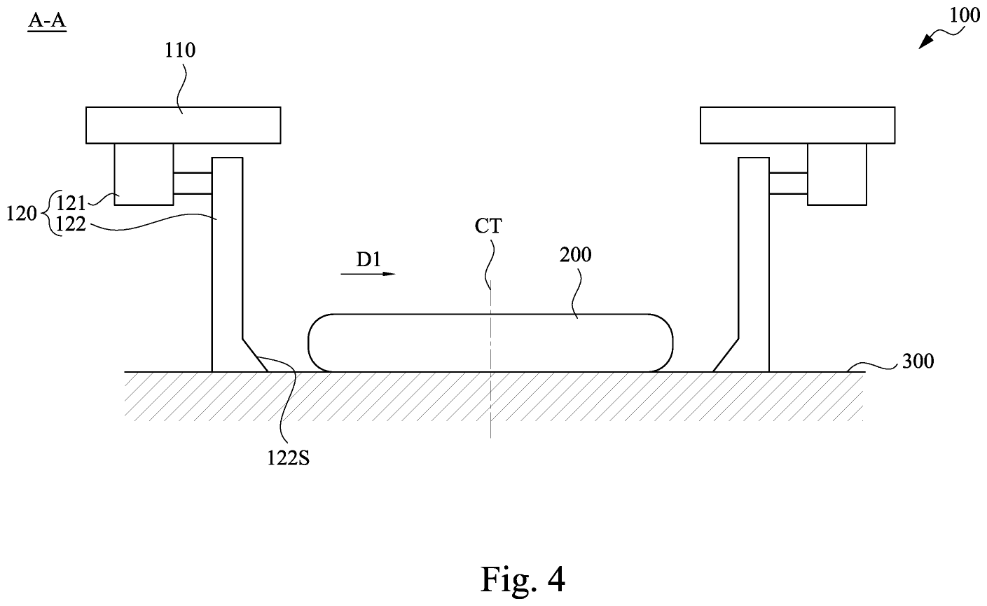

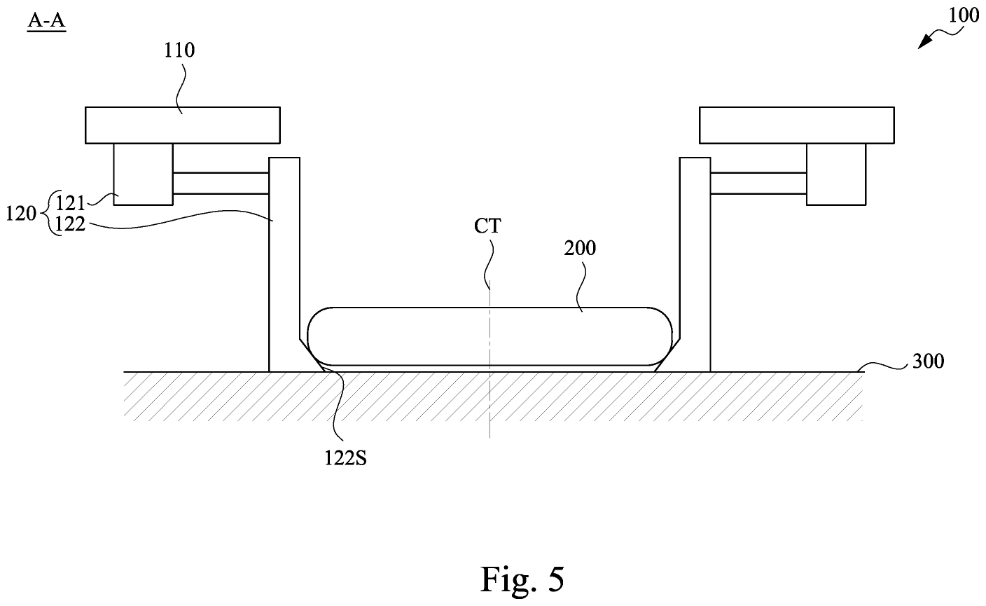

Reference is made to FIGS. 1-3. FIG. 1 is a top view of a wafer holding tool 100 according to an embodiment of the present disclosure. FIG. 2 is a front view of the wafer holding tool 100 of FIG. 1. FIG. 3 is a side view of the wafer holding tool 100 of FIG. 1. In this embodiment, as shown in FIGS. 1-3, a wafer holding tool 100 includes a main frame 110, a plurality of abutting devices 120, a moving device 130 and a handle 140. The abutting devices 120 are disposed on the main frame 110 and distributed about a center CT. Each of the abutting devices 120 is at least partially movable along a first direction D1 towards the center CT to abut against a wafer 200 (please see FIGS. 4-5 for the wafer 200). The moving device 130 is disposed on the main frame 110 and configured to hold and move the wafer 200 along a second direction D2 aligning with the center CT after the wafer 200 is abutted by the abutting devices 120. The handle 140 is disposed on the main frame 110 and extends along the second direction D2. In practice, the first direction D1 is a moving direction of each of the abutting devices 120 while the second direction D2 is an extension direction of the handle 140.

To be specific, as shown in FIGS. 1, the main frame 110 has a C-shape and has an inner edge 110E circularly curved about the center CT. Two opposite ends of the inner edge 110E define an opening OP therebetween. The handle 140 is disposed at a side of the main frame 110 opposite to the opening OP.

Furthermore, as shown in FIG. 1, the abutting devices 120 are symmetrically distributed on the main frame 110 about the center CT. In this way, the abutting devices 120 can securely abut against the wafer 200 in a surrounding manner.

Reference is made to FIGS. 4-5. FIG. 4 is a cross-sectional view along the section line A-A of FIG. 1, in which the abutting devices 120 are away from a wafer 200. FIG. 5 is an operational presentation of the wafer holding tool 100 of FIG. 4, in which the abutting devices 120 abut against the wafer 200 and the wafer 200 is lifted up. As shown in FIGS. 4-5, each of the abutting devices 120 includes a driving portion 121 and a spade 122. The driving portion 121 is connected with the main frame 110. The spade 122 is movably connected with the driving portion 121. The driving portion 121 is configured to drive the spade 122 to move along the first direction D1 relative to the main frame 110.

In addition, as shown in FIGS. 4-5, each of the spades 122 has an abutting surface 122S inclined to a corresponding one of the first directions D1. In practical applications, if the wafer 200 is located on a surface 300 as shown in FIG. 4, for example, when the driving portions 121 drive the spades 122 to respectively move along the first direction D1 relative to the main frame 110 towards the center CT to abut against the wafer 200, the abutting surface 122S of each of the spades 122 can lift up the wafer 200 relative to the surface 300. In other words, apart from abutting the edge of the wafer 200 by the spades 122, the wafer 200 is lifted up and does not contact with the surface 300 anymore. In practical applications, in order to prevent the wafer 200 from being damaged by the spades 122 when the spades 122 contact with the wafer 200, a protective layer of soft material can be disposed on each of the abutting surfaces 122S.

In this embodiment, as shown in FIG. 1, the wafer holding tool 100 further includes a first controlling device 150. The first controlling device 150 is disposed on the handle 140 and connected with the abutting devices 120. The first controlling device 150 is configured to control the abutting devices 120 to at least partially move to or away from the center CT. To be specific, the first controlling device 150 is configured to control the driving portions 121 to drive the spades 122 to move to abut against or leave from the wafer 200. In practice, the first controlling device 150 can be in the form of a button, a roller, a switch or the like. Moreover, the connections between the first controlling device 150, the driving portions 121 and the spades 122 can be achieved by electrical and/or mechanical components, which are not described in details herein.

Furthermore, in this embodiment, when the wafer 200 is securely abutted by the spades 122 of the abutting devices 120, the first controlling device 150 is further configured to lock the abutting devices 120, such that the spades 122 are fixed relative to the driving portions 121, and the wafer 200 is securely held by the spades 122 of the abutting devices 120.

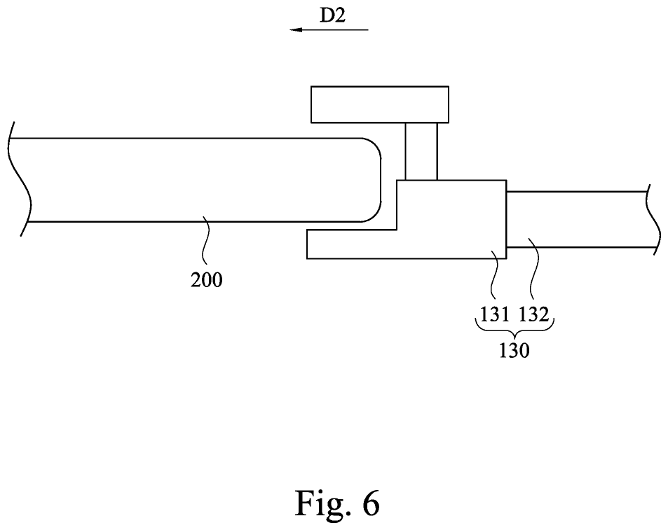

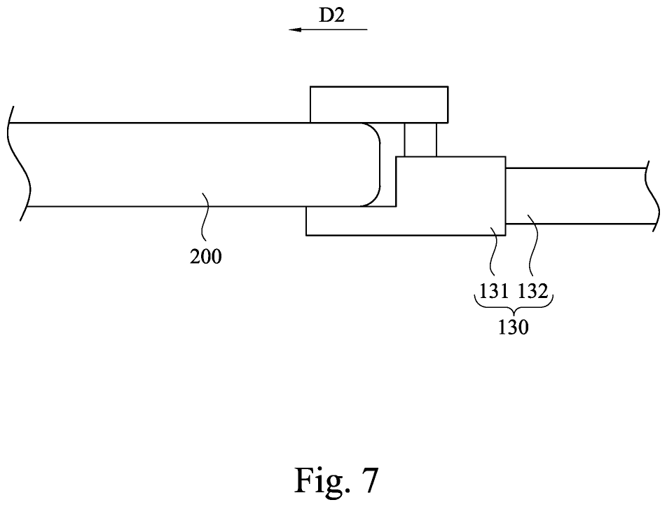

Reference is made to FIGS. 6-7. FIGS. 6-7 are partially enlarged side views of the moving device 130 of FIGS. 2-3. In this embodiment, as shown in FIGS. 2 and 6-7, the moving device 130 includes a clamp 131 and an extendable portion 132. The clamp 131 is configured to hold the wafer 200. The extendable portion 132 is connected between the clamp 131 and the main frame 110 (please refer to FIGS. 2-3 for the main frame 110). The extendable portion 132 is configured to extend or retract along the second direction D2 to move the clamp 131 relative to the main frame 110.

To be specific, after the wafer 200 is abutted and lifted up by the spades 122 of the abutting devices 120 as mentioned above, the extendable portion 132 of the moving device 130 extends and the clamp 131 is moved close to the edge of the wafer 200, as shown in FIG. 6. Afterwards, the clamp 131 is controlled to hold the wafer 200 by clamping, as shown in FIG. 7. At this point, when the wafer 200 is securely clamped by the clamp 131, the user can use the first controlling device 150 to control the driving portions 121, such that the spades 122 are moved away from the wafer 200 and the spades 122 are no longer in contact with the wafer 200. In practical applications, in order to prevent the wafer 200 from being damaged by the clamp 131 when the clamp 131 touches and clamps the wafer 200, a protective layer of soft material can be disposed on the clamp 131 for direct contact with the wafer 200.

In this embodiment, as shown in FIG. 1, the wafer holding tool 100 further includes a second controlling device 160. The second controlling device 160 is disposed on the handle 140 and connected with the extendable portion 132. The second controlling device 160 is configured to control the extendable portion 132 to at least partially extend or contract, such that the clamp 131 can be moved close to or away from the wafer 200. Similarly, in practice, the second controlling device 160 can be in the form of a button, a roller, a switch or the like. Moreover, the connections between the second controlling device 160, the extendable portion 132 and the clamp 131 can be achieved by electrical and/or mechanical components, which are not described in details herein.

In addition, the wafer holding tool 100 further includes a third controlling device 170. The third controlling device 170 is disposed on the handle 140 and connected with the extendable portion 132 and the clamp 131. The third controlling device 170 is configured to control the clamp 131 to open or close, such that the clamp 131 can clamp the wafer 200 or release the wafer 200. Similarly, in practice, the third controlling device 170 can be in the form of a button, a roller, a switch or the like. Moreover, the connections between the second controlling device 160, the extendable portion 132 and the clamp 131 can be achieved by electrical and/or mechanical components, which are not described in details herein. According to the actual situation, the second controlling device 160 and the third controlling device 170 can be linked up together or disposed independently of each other.

Furthermore, in this embodiment, when the wafer 200 is securely clamped and held by the clamp 131 of the moving device 130, the third controlling device 170 is further configured to lock the extendable portion 132 and the clamp 131, such that the clamp 131 is fixed relative to the extendable portion 132, and the wafer 200 is securely held by the clamp 131 of the moving device 130.

As shown in FIGS. 1-3, the wafer holding tool 100 further includes at least a pair of positioning protrusions 180. The positioning protrusions 180 are separated from each other and disposed on a side of the main frame 110 away from the handle 140. After the wafer 200 is held by the clamp 131, the wafer holding tool 100 can be moved close to the opening of a front opening unified pod (FOUP). In practice, the positioning protrusions 180 can be used to snap with the slot positions of the FOUP, such that the wafer 200 held by the clamp 131 can be properly put into the FOUP at a correct level.

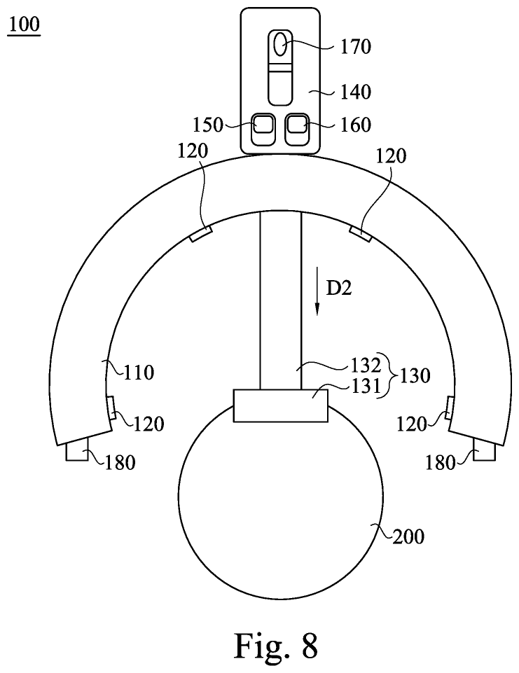

Reference is made to FIG. 8. FIG. 8 is a top view of the wafer holding tool 100 of FIG. 1, in which the wafer 200 is moved by the moving device 130 relative to the main frame 110. In this embodiment, the third controlling device 170 is also configured to further control the extendable portion 132 to at least partially extend or contract, such that the clamp 131 together with the wafer 200 can be moved to a further extent. As shown in FIG. 8, the wafer 200 is moved farther away from the handle 140, which helps to put the wafer 200 into the FOUP.

In conclusion, the aforementioned embodiments of the present disclosure have at least the following advantages:

(1) Since the wafer holding tool can be used to securely hold and put a wafer into a FOUP, the user is avoided from touching the wafer directly with his bare hand(s). Thus, the risk of contamination of the wafer is reduced.

(2) Since a wafer can be lifted up by the spades of the abutting devices when the spades abut against the edge of the wafer from different directions, the clamp of the moving device can easily hold and clamp the edge of the wafer even if the wafer if originally placed on a flat surface.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A wafer holding tool, comprising:
a main frame;
a plurality of abutting devices disposed on the main frame about a center, each of the abutting devices being at least partially movable along a first direction towards the center to abut against a wafer;
a moving device disposed on the main frame and configured to hold and move the wafer after the wafer being abutted by the abutting devices; and
a handle disposed on the main frame and extending along a second direction aligning with the center.

2. The wafer holding tool of claim 1, wherein each of the abutting devices comprises:
a driving portion connected with the main frame; and
a spade movably connected with the driving portion, the driving portion is configured to drive the spade to move along the first direction.

3. The wafer holding tool of claim 2, wherein each of the spades has an abutting surface inclined to a corresponding one of the first directions.

4. The wafer holding tool of claim 1, wherein the abutting devices are symmetrically distributed about the center.

5. The wafer holding tool of claim 1, wherein the main frame has an inner edge circularly curved about the center, and two opposite ends of the inner edge define an opening therebetween.

6. The wafer holding tool of claim 1, further comprising:
a first controlling device disposed on the handle and connected with the abutting devices, the first controlling device being configured to control the abutting devices to at least partially move to or away from the center.

7. The wafer holding tool of claim 6, wherein the first controlling device is further configured to lock the abutting devices.

8. The wafer holding tool of claim 1, wherein the moving device comprises:
a clamp configured to hold the wafer; and
an extendable portion connected between the clamp and the main frame, the extendable portion is configured to extend or retract along the second direction to move the clamp relative to the main frame.

9. The wafer holding tool of claim 8, further comprising:
a second controlling device disposed on the handle and connected with the extendable portion, the second controlling device being configured to control the extendable portion to at least partially extend or contract; and
a third controlling device disposed on the handle and connected with the extendable portion and the clamp, the third controlling device being configured to control the clamp to open or close and to further control the extendable portion to at least partially extend or contract.

10. The wafer holding tool of claim 9, wherein the third controlling device is further configured to lock the extendable portion and the clamp.

11. The wafer holding tool of claim 1, further comprising:
at least a pair of positioning protrusions separated from each other and disposed on a side of the main frame away from the handle.

12. A wafer holding tool, comprising:
a C-shaped frame defining an opening;
a handle disposed at a side of the C-shaped frame opposite to the opening; and
a moving device disposed on the main frame and configured to clamp and move a wafer along an extension direction of the handle.

13. The wafer holding tool of claim 12, further comprising:
a plurality of abutting devices disposed on the C-shaped frame and configured to move to abut against the wafer in a surrounding manner before the wafer is clamped by the moving device.

14. The wafer holding tool of claim 13, wherein each of the abutting devices comprises:
a driving portion connected with the C-shaped frame; and
a spade movably connected with the driving portion, the driving portion is configured to drive the spade to move relative to the C-shaped frame.

15. The wafer holding tool of claim 14, wherein each of the spades has an abutting surface inclined to a moving direction of a corresponding one of the spades.

16. The wafer holding tool of claim 14, further comprising:
a first controlling device disposed on the handle and connected with the driving portions, the first controlling device being configured to control the driving portions to drive the spades to move to abut against or leave from the wafer.

17. The wafer holding tool of claim 12, wherein the moving device comprises:
a clamp configured to hold the wafer; and
an extendable portion connected between the clamp and the C-shaped frame, the extendable portion is configured to extend or retract to move the clamp relative to the main frame.

18. The wafer holding tool of claim 17, further comprising:
a second controlling device disposed on the handle and connected with the extendable portion, the second controlling device being configured to control the extendable portion to at least partially extend or contract; and
a third controlling device disposed on the handle and connected with the extendable portion and the clamp, the third controlling device being configured to control the clamp to open or close and to further control the extendable portion to at least partially extend or contract.

19. The wafer holding tool of claim 12, further comprising:
at least a pair of positioning protrusions separated from each other and disposed on a side of the C-shaped frame away from the handle.
